(19) United States
(12) Patent Application Publication
(10) Pub. No.: US 2024/0243042 A1
(43) Pub. Date: Jul. 18, 2024

(54) POWER SEMICONDUCTOR MODULE AND DISCRETE POWER SEMICONDUCTOR DEVICE HAVING AN ACTIVE TEMPERATURE SENSOR DIE, AND CORRESPONDING METHODS OF PRODUCTION

(71) Applicant: Infineon Technologies AG, Neubiberg (DE)

(72) Inventors: Tillmann Walther, Dresden (DE); Markus Neubert, München (DE); Andrey Kravchenko, Dresden (DE); Christian Schweikert, München (DE)

(21) Appl. No.: 18/097,358

(22) Filed: Jan. 16, 2023

(51) Int. Cl. H01L 23/495; H01L 23/00; H01L 25/065

(52) U.S. Cl. CPC H01L 23/49568; H01L 23/49558; H01L 23/49575; H01L 24/48; H01L 25/0655; H01L 2224/48091

(57) ABSTRACT

A power semiconductor module includes: an electrically insulative frame; a plurality of power semiconductor dies housed within the electrically insulative frame and electrically interconnected to form a power electronics circuit; an active temperature sensor die housed within the electrically insulative frame and including an integrated current source; a first temperature sense terminal electrically connected to a first contact pad of the active temperature sensor die; and a second temperature sense terminal electrically connected to a second contact pad of the active temperature sensor die. A discrete power semiconductor device and methods of producing the module and discrete device are also described.

### BACKGROUND

The usage of a sinterable temperature sensor for temperature sensing within power semiconductor modules reduces overall cost and effort for modules where the main power dies (chips) such as SiC-MOS, IGBT (insulated gate bipolar transistor) and high-voltage diodes, etc. are also sintered. Sintering is a process of compacting and forming a solid mass of material by pressure and/or heat without melting the material to the point of liquefaction, whereas soldering is a process of joining two metallic surfaces by melting an alloy between the metallic surfaces.

Conventional sinterable temperature sensors for power semiconductor modules typically use a polysilicon diode. To detect the temperature with such a sensor device, an additional external constant current source is required, which imposes restrictions on the choice of the gate-driver and/or the printed circuit board compared to a solution where the temperature detection is based only on a voltage source using an NTC (negative temperature coefficient) resistor. However, conventional NTC resistors are only solderable.

### SUMMARY

According to an embodiment of a power semiconductor module, the power semiconductor module comprises: an electrically insulative frame; a plurality of power semiconductor dies housed within the electrically insulative frame and electrically interconnected to form a power electronics circuit; an active temperature sensor die housed within the electrically insulative frame and including an integrated current source; a first temperature sense terminal electrically connected to a first contact pad of the active temperature sensor die; and a second temperature sense terminal electrically connected to a second contact pad of the active temperature sensor die.

According to an embodiment of a discrete power semiconductor device, the discrete power semiconductor device comprises: a power transistor die attached to a substrate; an active temperature sensor die that includes an integrated current source; a mold compound encapsulating the power transistor die and the active temperature sensor die; a first temperature sense lead electrically connected to a first contact pad of the active temperature sensor die and at least partly uncovered by the mold compound; and a second temperature sense lead electrically connected to a second contact pad of the active temperature sensor die and at least partly uncovered by the mold compound.

According to an embodiment of a method of producing a power semiconductor module, the method comprises: housing a plurality of power semiconductor dies and an active temperature sensor die in an electrically insulative frame, the active temperature sensor die including an integrated current source; electrically interconnecting the plurality of power semiconductor dies to form a power electronics circuit; electrically connecting a first temperature sense terminal to a first contact pad of the active temperature sensor die; and electrically connecting a second temperature sense terminal to a second contact pad of the active temperature sensor die.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a top plan view of an embodiment of a power semiconductor module that includes power semiconductor dies and an active temperature sensor die with integrated current source housed within an electrically insulative frame of the module.

FIG. 2 illustrates a side perspective view of an embodiment of attaching the power semiconductor dies and the active temperature sensor die to a substrate, taken along the line labelled A-A′ in FIG. 1.

FIG. 3 illustrates a top plan view of another embodiment of a power semiconductor module that includes power semiconductor dies and an active temperature sensor die with integrated current source housed within an electrically insulative frame of the module.

FIG. 4 illustrates a cross-sectional view of the power semiconductor module along the line labelled B-B′ in FIG. 3.

FIG. 5 illustrates a top plan view of an embodiment of a discrete power semiconductor device that includes an active temperature sensor die with integrated current source.

FIG. 6 illustrates a top plan view of another embodiment of a discrete power semiconductor device that includes an active temperature sensor die with integrated current source.

FIG. 7 illustrates a top plan view of another embodiment of a discrete power semiconductor device that includes an active temperature sensor die with integrated current source.

FIG. 8 illustrates a schematic diagram of an embodiment of the integrated current source included in the active temperature sensor die.

FIG. 9 illustrates a schematic diagram of another embodiment of the integrated current source included in the active temperature sensor die.

FIG. 10 illustrates a schematic diagram of another embodiment of the integrated current source included in the active temperature sensor die.

### DETAILED DESCRIPTION

The embodiments described herein provide both a power semiconductor module and a discrete power semiconductor device each having an active temperature sensor die that includes an integrated current source. Additional analog circuitry may be included in the power semiconductor module and/or the discrete power semiconductor device to detect the temperature within the module/discrete device. The embodiments described herein enable temperature sensing without an external constant current source.

Described next, with reference to the figures, are exemplary embodiments of the power semiconductor module, discrete power semiconductor device, and methods of producing the power semiconductor module and discrete power semiconductor device. Any of the active temperature sensor embodiments described herein may be used interchangeably unless otherwise expressly stated.

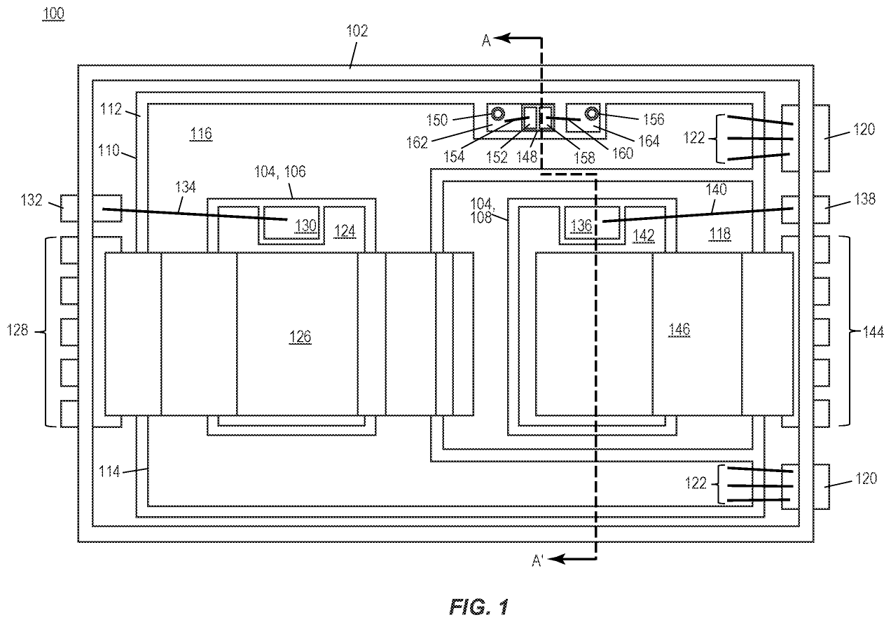

FIG. 1 illustrates a top plan view of an embodiment of a power semiconductor module 100. The power semiconductor module 100 includes an electrically insulative frame 102 and a plurality of power semiconductor dies 104 housed within the electrically insulative frame 102 and electrically interconnected to form a power electronics circuit. A lid (not shown) may be provided to enclose the power semiconductor dies 104 within the electrically insulative frame 102.

The power semiconductor module 100 may form part of a power electronics device for use in various power applications such as in a DC/AC inverter, a DC/DC converter, an AC/DC converter, a DC/AC converter, an AC/AC converter, a multi-phase inverter, an H-bridge, etc. The power electronics circuit housed within the power semiconductor module 100 may be a half bridge circuit, for example.

In FIG. 1, a single a half bridge circuit 102 is shown. However, this is just an example. The power semiconductor module 100 may include more than one half bridge circuit, e.g., three (3) half bridge circuits in the case of a 3-phase power converter. More generally, the power semiconductor module 100 may include a single half bridge circuit for a single-phase system or more than one half bridge circuit for a multi-phase system or other types of power electronics circuits such as one or more full bridges, asymmetrical half-bridges, diode rectifiers, etc.

The electrically insulative frame 102 may be a single contiguous frame or comprise a separate frame subunit for each half bridge circuit or other type of power electronics circuit housed within the power semiconductor module 100. In the case of separate frame subunits, the frame subunits may be attached to one another, e.g., by plastic welding, gluing, etc.

In the case of a half bridge power electronics circuit, each half bridge housed within the power semiconductor module 100 includes one or more high-side power semiconductor dies 106 and one or more low-side power semiconductor dies 108. In the cases of multiple dies for each side of the half bridge, the high-side power semiconductor dies 106 of each half bridge are electrically connected in parallel as are the low-side power semiconductor dies 108 of each half bridge.

The high-side power semiconductor die(s) 106 of each half bridge may be attached to at least one substrate 110. The low-side power semiconductor die(s) 108 of each half bridge likewise may be attached to the same or different substrate 110. The high-side and low-side power semiconductor dies 106, 108 may be Si or SiC power MOSFET (metal-oxide-semiconductor field-effect transistor) dies, HEMT (high-electron mobility transistor) dies, IGBT (insulated-gate bipolar transistor) dies, JFET (junction filed-effect transistor) dies, etc. Additional types of semiconductor dies may be included in the power semiconductor module 100, such as power diode dies, logic dies, controller dies, gate driver dies, etc.

Each substrate 110 included in the power semiconductor module 100 may have an electrically insulative body 112 and a patterned metallization 114 applied to or formed on the electrically insulative body 112. For example, the substrate 110 may be a power electronics carrier such as a DCB (direct copper bonded) substrate, an AMB (active metal brazed) substrate, an IMS (insulated metal substrate), etc. The patterned metallization 114 instead may be a lead frame, for example.

In the case of a half bridge power electronics circuit and vertical power semiconductor dies 104, a drain or collector contact pad (out of view) at the backside of the high-side power semiconductor die(s) 106 is attached to a first part 116 of the patterned metallization 114 and a drain or collector contact pad (out of view) at the backside of the low-side power semiconductor die(s) 108 is attached to a second part 118 of the patterned metallization 114. The first part 116 of the patterned metallization 114 is electrically connected to a DC+ terminal(s) 120 of the power semiconductor module 100, e.g., by one or electrical conductors 122 such as one or more bond wires, a metal clip, part of an overlying lead frame, etc.

The second part 118 of the patterned metallization 114 is electrically connected to a source or emitter contact pad 124 at the frontside of the high-side power semiconductor die(s) 106 to form a phase/ac node of the half bridge, e.g., by one or electrical conductors 126 such as one or more bond wires, a metal clip, etc. The same or different electrical conductor 126 is electrically connected to a phase/ac terminal 128 of the power semiconductor module 100.

A gate contact pad 130 at the frontside of the high-side power semiconductor die(s) 106 is electrically connected to a high-side terminal 132 of the power semiconductor module 100, e.g., by one or electrical conductors 134 such as one or more bond wires, a metal clip, part of an overlying lead frame, etc. A gate contact pad 136 at the frontside of the low-side power semiconductor die(s) 108 is electrically connected to a low-side terminal 138 of the power semiconductor module 100, e.g., by one or electrical conductors 140 such as one or more bond wires, a metal clip, part of an overlying lead frame, etc. A source or emitter contact pad 142 at the frontside of the low-side power semiconductor die(s) 108 is electrically connected to a ground or DC− terminal 144 of the power semiconductor module 100, e.g., by an electrical conductor 146 such as one or more bond wires, a metal clip, etc.

The power semiconductor module 100 also includes an active temperature sensor die 148 housed within the electrically insulative frame 102. The active temperature sensor die 148 includes an integrated current source. In one embodiment, the integrated current source is a temperature dependent current source. For example, a PTAT (proportional to absolute temperature) part of a bandgap reference circuit may be integrated in the active temperature sensor die 148 and combined with a resistor or diode. The PTAT circuit outputs a temperature dependent current that can be internally or externally converted to a digital signal. In another embodiment, the integrated current source included in the active temperature sensor die 148 is a constant current source.

A first temperature sense terminal 150 of the power semiconductor module 100 is electrically connected to a first contact pad 152 of the active temperature sensor die 148, e.g., by an electrical conductor 154 such as one or more bond wires, a metal clip, part of an overlying lead frame, etc. Depending on the design and layout of the electrically insulative frame 102, the first temperature sense terminal 150 may protrude out of the electrically insulative frame 102. If a lid is included, the first temperature sense terminal 150 may protrude through the lid.

A second temperature sense terminal 156 of the power semiconductor module 100 is electrically connected to a second contact pad 158 of the active temperature sensor die 148, e.g., by an electrical conductor 160 such as one or more bond wires, a metal clip, part of an overlying lead frame, etc. Depending on the design and layout of the electrically insulative frame 102, the second temperature sense terminal 156 may protrude out of the electrically insulative frame 102. If a lid is included, the second temperature sense terminal 156 may protrude through the lid.

The active temperature sensor die 148 may be attached to a part 162 of the patterned metallization 114 of the substrate 110. One of the temperature sense terminals 150, 156 of the power semiconductor module 100 may be attached to the same part 162 of the patterned metallization 114 of the substrate 110 as the active temperature sensor die 148, e.g., as shown in FIG. 1. The other one of the temperature sense terminals 150, 156 of the power semiconductor module 100 may be attached to another part 164 of the patterned metallization 114 of the substrate 110.

The temperature sense terminals 150, 156 of the power semiconductor module 100 may be pins such as press-fit pins, for example. Press-fit pins have a pin geometry that enables plastic deformation in an upper region of the pin. After insertion into an opening in a metallization such as the metallization of a PCB (printed circuit board), contact between the pin and the metallization develops and elastic and plastic deformations generate a large contact area. The temperature sense terminals 150, 156 instead may be surface mount or through hole leads, for example.

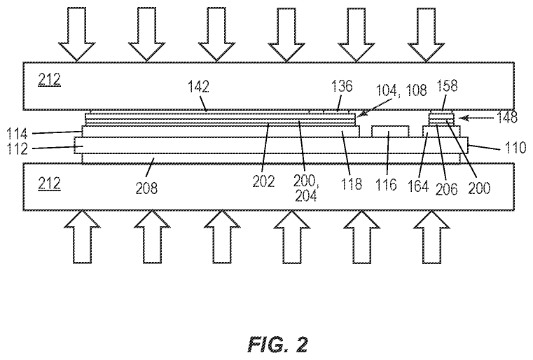

FIG. 2 illustrates a side perspective view of an embodiment of attaching the power semiconductor dies 104 and the active temperature sensor die 148 to a substrate 110, taken along the line labelled A-A′ in FIG. 1. According to this embodiment, the power semiconductor dies 104 and the active temperature sensor die 148 are attached to the substrate 110 by a concurrent sintering process. The power semiconductor dies 104 and the active temperature sensor die 148 may be bare dies capable of withstanding the concurrent sintering process (temperature and/or pressure) and each having a sinterable metal backside surface 200, e.g., such as a silver material. Further according to this embodiment, the active temperature sensor die 148 has the same height as the power semiconductor dies 104 within a tolerance defined by the semiconductor technology used to fabricate the dies 104, 148, e.g., about 5 to 10%.

Before housing the power semiconductor dies 104 and the active temperature sensor die 148 within the electrically insulative frame 102, the power semiconductor dies 104 and the active temperature sensor die 148 are concurrently sintered to the substrate 110. The concurrent sintering process may be performed by using one or more supports 212 to press the power semiconductor dies 104 and the active temperature sensor die 148 against the substrate 110 and/or to apply heat, as indicated by the upward and downward facing arrows in FIG. 2.

The concurrent sintering process compacts and forms solid masses of material by pressure and/or heat without melting the material to the point of liquefaction. A first sintered mass of material 202 attaches the sinterable metal backside surface 200, e.g., a drain or collector contact pad 204 of the low-side power semiconductor die(s) 108 to the corresponding part 118 of the patterned metallization 114. A second sintered mass of material 206 attaches the sinterable metal backside surface 200 of the active temperature sensor die 148 to another part 164 of the patterned metallization 114. An additional sintered mass of material (out of view in FIG. 2) attaches the sinterable metal backside surface 200, e.g., a drain or collector contact pad 204 of the high-side power semiconductor die(s) 106 to the corresponding part 116 of the patterned metallization 114. Instead of a sintered connection, the power semiconductor dies 104 and the active temperature sensor die 148 may be soldered to the substrate 110, e.g., where the sintered masses of material 202, 206 shown in FIG. 2 are instead solder joints.

After completion of the concurrent sintering process or a soldering process for attaching the power semiconductor dies 104 and the active temperature sensor die 148 to a substrate 110, the power semiconductor dies 104 and the active temperature sensor die 148 are housed within the electrically insulative frame 102. The topside contact pad connections and lead connections 126, 134, 140, 146, 154, 160 shown in FIG. 1 are also formed after completion of the concurrent sintering process, as are the temperature sensor terminal connections 150, 156. The power module substrate 110 may have a backside metallization 208, e.g., as shown in FIG. 2.

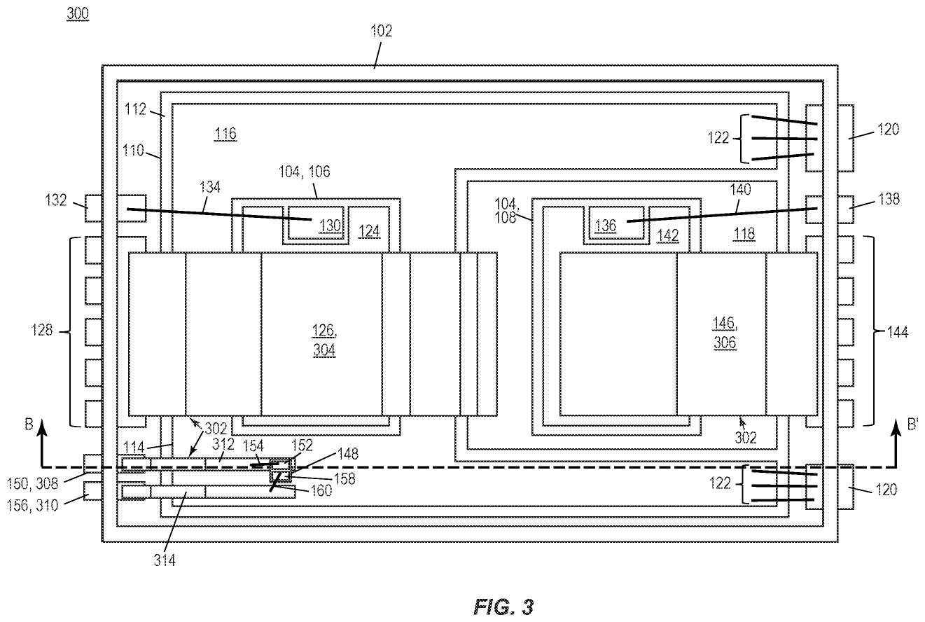

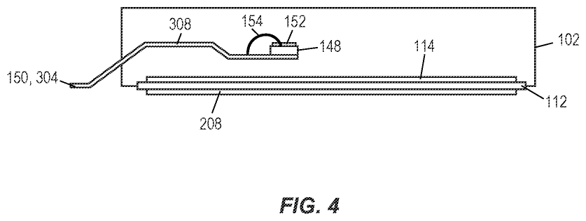

FIG. 3 illustrates a top plan view of an embodiment of a power semiconductor module 300 and FIG. 4 illustrates a cross-sectional view of the power semiconductor module 300 along the line labelled B-B′ in FIG. 3. The cross-sectional view in FIG. 4 omits the power semiconductor dies 104, the module leads 120, 128, 132, 138, 144 for the power semiconductor dies 104, and the corresponding internal connections 122, 124, 134, 140, 146, to emphasize the arrangement of the active temperature sensor die 148 within the power semiconductor module 300.

The embodiment illustrated in FIG. 3 is similar to the embodiment illustrated in FIG. 1. In FIG. 3, a clip frame or lead frame 302 is housed in the electrically insulative frame 102 above the power semiconductor dies 104. The conductor 126 that forms the phase/ac node of the half bridge circuit is a first clip 304 of the overlying clip frame or lead frame 302 and the electrical conductor 146 that electrically connects the source or emitter contact pad 142 at the frontside of the low-side power semiconductor die(s) 108 to the ground or DC− terminal 144 of the power semiconductor module 300 is a second clip 306 of the clip frame or lead frame 302. According to this embodiment, the active temperature sensor die 148 is attached to the clip frame or lead frame 302, e.g., by solder, an adhesive, etc.

Further according to the embodiment illustrated in FIG. 3, the first and second temperature sense terminals 150, 156 of the power semiconductor module 300 are implemented as respective leads 308, 310. A clip 312 of the clip frame or lead frame 302 electrically connects the first contact pad 152 of the active temperature sensor die 112 to the first temperature sense terminal lead 308. Another clip 314 of the clip frame or lead frame 302 electrically connects the second contact pad 158 of the active temperature sensor die 112 to the second temperature sense terminal lead 310. The temperature sense terminals 150, 156 instead may be implemented as respective press-fit pins, e.g., similar to what is shown in FIG. 1 but with the press-fit pins attached to the respective clips 312, 314 of the clip frame or lead frame 302 instead of the substrate metallization 114.

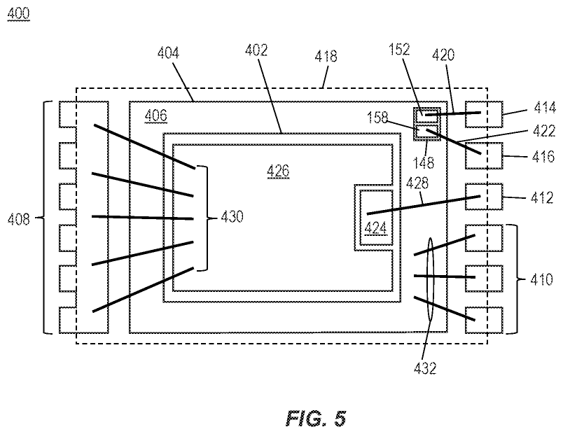

FIG. 5 illustrates a top plan view of an embodiment of a discrete power semiconductor device 400 that includes the active temperature sensor die 148 with integrated current source. The discrete power semiconductor device 400 also includes a power transistor die 402 attached to a substrate 404. The power transistor die 402 may be a Si or SiC power MOSFET die, a HEMT die, an IGBT die, a JFET die, etc. In FIG. 5, the substrate 404 is a die paddle 406 of a lead frame. The lead frame also has leads 408, 410, 412, 414, 416 for enabling external electrical connections to the power transistor die 402 and the active temperature sensor die 148. The leads 408, 410, 412, 414, 416 of the discrete power semiconductor device 400 may be surface mount leads, through hole leads, press-fit pins, etc.

The discrete power semiconductor device 400 further includes a mold compound 418 that encapsulates the power transistor die 402 and the active temperature sensor die 148. The mold compound 418 is illustrated as a dashed rectangle in FIG. 5 to provide an unobstructed view of the internal components of the discrete power semiconductor device 400.

A first temperature sense lead 414 of the discrete power semiconductor device 400 is electrically connected to the first contact pad 152 of the active temperature sensor die 112, e.g., by an electrical conductor 420 such as one or more bond wires, a metal clip, etc. A second temperature sense lead 416 of the discrete power semiconductor device 400 is electrically connected to the second contact pad 158 of the active temperature sensor die 112, e.g., by another electrical conductor 422 such as one or more bond wires, a metal clip, etc.

In FIG. 5, the electrical conductors 420, 422 that electrically connect the contact pads 152, 158 of the active temperature sensor die 112 to the respective temperature sense leads 414, 416 of the discrete power semiconductor device 400 are embedded in the mold compound 418. The temperature sense leads 414, 416 of the discrete power semiconductor device 400 are at least partly uncovered by the mold compound 418. In the case of a lead frame die paddle 406 as the substrate 404, the temperature sense leads 414, 416 may be part of the same lead frame that includes the die paddle 406. The substrate 404 instead may be a power electronics carrier such as a DCB substrate, an AMB substrate, an IMS, etc.

In FIG. 5, the power transistor die 402 is a vertical power transistor die with a gate contact pad 424 and a source or emitter contact pad 426 at the frontside of the die 402 and a drain or collector contact pad at the backside of the die 402 which is out of view in FIG. 5. An electrical conductor 428 such as one or more bond wires, a metal clip, etc. electrically connects the gate contact pad 424 to the corresponding lead 412 of the discrete power semiconductor device 400. Another electrical conductor 430 such as one or more bond wires, a metal clip, etc. electrically connects the source or emitter contact pad 426 to the corresponding lead 408 of the discrete power semiconductor device 400. Still another electrical conductor 432 such as one or more bond wires, a metal clip, etc. electrically connects the die paddle 406 which is at drain or collector potential to the corresponding lead(s) 410 of the discrete power semiconductor device 400.

In FIG. 5, the active temperature sensor die 148 is attached to the same substrate 404 as the power transistor die 402. In the case of a lead frame die paddle 406 as the substrate 404, both the power transistor die 402 and the active temperature sensor die 148 may be attached to the die paddle 406. In one embodiment, the power transistor die 402 and the active temperature sensor die 148 are soldered to the die paddle 406/substrate 404. In another embodiment, the power transistor die 402 and the active temperature sensor die 148 are sintered to the die paddle 406/substrate 404.

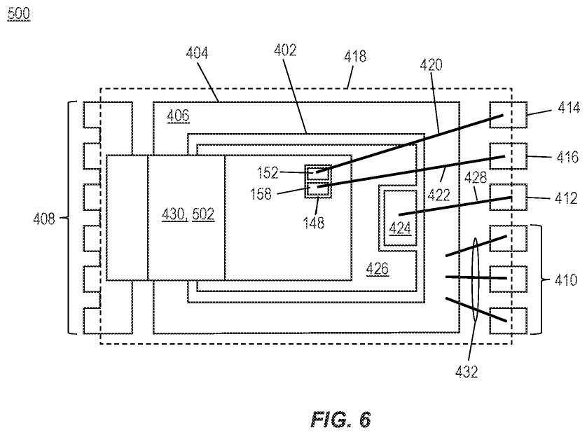

FIG. 6 illustrates a top plan view of another embodiment of a power semiconductor module 500. The embodiment illustrated in FIG. 6 is similar to the embodiment illustrated in FIG. 5. In FIG. 6, the electrical conductor 430 that electrically connects the source or emitter contact pad 426 of the power transistor die 402 to the corresponding leads 408 of the discrete power semiconductor device 400 is implemented as a metal clip 502 and the active temperature sensor die 148 is attached to the metal clip 502. The active temperature sensor die 148 may be attached to the metal clip 502 by a sintered connection, solder joint, adhesive, etc.

FIG. 7 illustrates a top plan view of another embodiment of a power semiconductor module 600. The embodiment illustrated in FIG. 7 is similar to the embodiment illustrated in FIG. 5. In FIG. 7, the active temperature sensor die 148 is attached to the side of the power transistor die 402 that faces away from the substrate 404. For example, the active temperature sensor die 148 may be attached to the source or emitter contact pad 426 of the power transistor die 402. The active temperature sensor die 148 may be attached to the side of the power transistor die 402 that faces away from the substrate 404 by a sintered connection, solder joint, adhesive, etc.

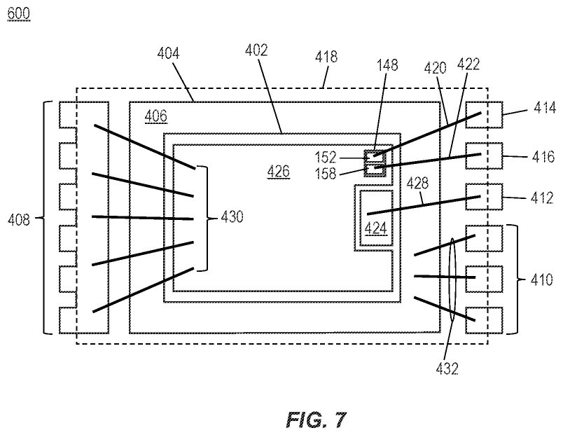

FIG. 8 illustrates a schematic diagram of an embodiment of the integrated current source included in the active temperature sensor die 148. According to this embodiment, the integrated current source includes a constant current source 700 that generates a constant current I. The constant current I flows through a temperature dependent diode D₁ that is in series with the constant current source 700 to generate a temperature dependent output voltage Vs. A resistor R1 also in series with the constant current source 700 forms a voltage divider in combination with the constant current source 700 and the temperature dependent diode D₁, such that the temperature dependent output voltage Vs of the integrated current source is a fraction of the input voltage V1.

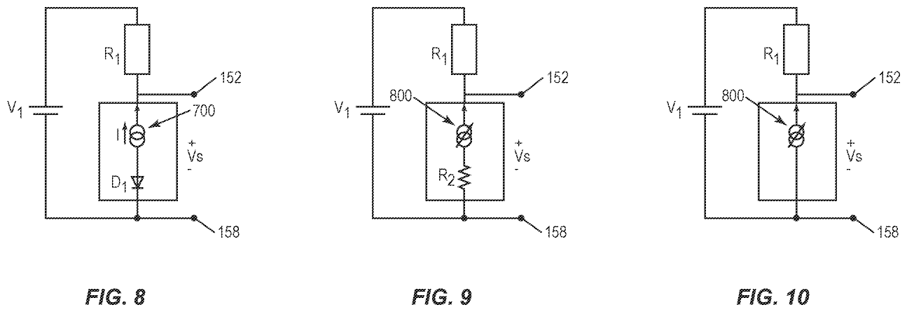

FIG. 9 illustrates a schematic diagram of another embodiment of the integrated current source included in the active temperature sensor die 148. According to this embodiment, the integrated current source includes a temperature dependent current source 800 that generates a temperature dependent current. The temperature dependent current flows through a resistor R₂ (or diode) that is in series with the constant current source 700 to generate the temperature dependent output voltage Vs.

FIG. 10 illustrates a schematic diagram of another embodiment of the integrated current source included in the active temperature sensor die 148 includes. The embodiment illustrated in FIG. 10 is similar to the embodiment illustrated in FIG. 9. In FIG. 10, the lower resistor R₂ (or lower diode) is omitted. In this case, the functionality of the lower resistor R₂ (or lower diode) may be integrated into the temperature dependent current source 800 such that a separate physical resistor or diode may be omitted.

Although the present disclosure is not so limited, the following numbered examples demonstrate one or more aspects of the disclosure.

Example 1. A power semiconductor module, comprising: an electrically insulative frame; a plurality of power semiconductor dies housed within the electrically insulative frame and electrically interconnected to form a power electronics circuit; an active temperature sensor die housed within the electrically insulative frame and including an integrated current source; a first temperature sense terminal electrically connected to a first contact pad of the active temperature sensor die; and a second temperature sense terminal electrically connected to a second contact pad of the active temperature sensor die.

Example 2. The power semiconductor module of example 1, wherein the plurality of power semiconductor dies and the active temperature sensor die are attached to a substrate.

Example 3. The power semiconductor module of example 2, wherein the plurality of power semiconductor dies and the active temperature sensor die are soldered to the substrate.

Example 4. The power semiconductor module of example 2, wherein the plurality of power semiconductor dies and the active temperature sensor die are sintered to the substrate.

Example 5. The power semiconductor module of any of examples 1 through 4, wherein the first temperature sense terminal is a first press-fit pin attached to the substrate, and wherein the second temperature sense terminal is a second press-fit pin attached to the substrate.

Example 6. The power semiconductor module of any of examples 1 through 5, further comprising: a clip frame or lead frame housed within the electrically insulative frame above the plurality of power semiconductor dies and electrically connected to the plurality of power semiconductor dies, wherein the active temperature sensor die is attached to the clip frame or lead frame.

Example 7. The power semiconductor module of example 6, wherein the first temperature sense terminal is a first press-fit pin attached to the clip frame or lead frame, and wherein the second temperature sense terminal is a second press-fit pin attached to the clip frame or lead frame.

Example 8. The power semiconductor module of any of examples 1 through 7, wherein the integrated current source is a temperature dependent current source.

Example 9. The power semiconductor module of any of examples 1 through 7, wherein the integrated current source is a constant current source.

Example 10. A discrete power semiconductor device, comprising: a power transistor die attached to a substrate; an active temperature sensor die that includes an integrated current source; a mold compound encapsulating the power transistor die and the active temperature sensor die; a first temperature sense lead electrically connected to a first contact pad of the active temperature sensor die and at least partly uncovered by the mold compound; and a second temperature sense lead electrically connected to a second contact pad of the active temperature sensor die and at least partly uncovered by the mold compound.

Example 11. The discrete power semiconductor device of example 10, wherein the active temperature sensor die is attached to the substrate.

Example 12. The discrete power semiconductor device of example 11, wherein the power transistor die and the active temperature sensor die are soldered to the substrate.

Example 13. The discrete power semiconductor device of example 11, wherein the power transistor die and the active temperature sensor die are sintered to the substrate.

Example 14. The discrete power semiconductor device of any of examples 10 through 13, further comprising: a metal clip attached to a contact pad of the power transistor die that faces away from the substrate, wherein the active temperature sensor die is attached to the metal clip.

Example 15. The discrete power semiconductor device of any of examples 10 through 14, wherein the active temperature sensor die is attached to a side of the power transistor die that faces away from the substrate.

Example 16. The discrete power semiconductor device of any of examples 10 through 15, wherein the substrate is a die paddle of a lead frame, wherein the first temperature sense lead and the second temperature sense lead are part of the lead frame, wherein the first contact pad of the active temperature sensor die is electrically connected to the first temperature sense lead by a first bond wire embedded in the mold compound, and wherein the second contact pad of the active temperature sensor die is electrically connected to the second temperature sense lead by a second bond wire embedded in the mold compound.

Example 17. The discrete power semiconductor device of example 16, wherein the active temperature sensor die is attached to the die paddle.

Example 18. A method of producing a power semiconductor module, the method comprising: housing a plurality of power semiconductor dies and an active temperature sensor die in an electrically insulative frame, the active temperature sensor die including an integrated current source; electrically interconnecting the plurality of power semiconductor dies to form a power electronics circuit; electrically connecting a first temperature sense terminal to a first contact pad of the active temperature sensor die; and electrically connecting a second temperature sense terminal to a second contact pad of the active temperature sensor die.

Example 19. The method of example 18, further comprising: before housing the plurality of power semiconductor dies and the active temperature sensor die in the electrically insulative frame, attaching the plurality of power semiconductor dies and the active temperature sensor die to a substrate.

Example 20. The method of example 19, wherein attaching the plurality of power semiconductor dies and the active temperature sensor die to the substrate comprises concurrently sintering the plurality of power semiconductor dies and the active temperature sensor die to the substrate.

Example 21. The method of any of examples 18 through 20, further comprising: housing a clip frame or lead frame in the electrically insulative frame above the plurality of power semiconductor dies; electrically connecting the clip frame or lead frame to the plurality of power semiconductor dies; and attaching the active temperature sensor die to the clip frame or lead frame.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor module, comprising:
an electrically insulative frame;
a plurality of power semiconductor dies housed within the electrically insulative frame and electrically interconnected to form a power electronics circuit;
an active temperature sensor die housed within the electrically insulative frame and including an integrated current source;
a first temperature sense terminal electrically connected to a first contact pad of the active temperature sensor die; and
a second temperature sense terminal electrically connected to a second contact pad of the active temperature sensor die.

2. The power semiconductor module of claim 1, wherein the plurality of power semiconductor dies and the active temperature sensor die are attached to a substrate.

3. The power semiconductor module of claim 2, wherein the plurality of power semiconductor dies and the active temperature sensor die are soldered to the substrate.

4. The power semiconductor module of claim 2, wherein the plurality of power semiconductor dies and the active temperature sensor die are sintered to the substrate.

5. The power semiconductor module of claim 1, wherein the first temperature sense terminal is a first press-fit pin attached to the substrate, and wherein the second temperature sense terminal is a second press-fit pin attached to the substrate.

6. The power semiconductor module of claim 1, further comprising:
a clip frame or lead frame housed within the electrically insulative frame above the plurality of power semiconductor dies and electrically connected to the plurality of power semiconductor dies,
wherein the active temperature sensor die is attached to the clip frame or lead frame.

7. The power semiconductor module of claim 6, wherein the first temperature sense terminal is a first press-fit pin attached to the clip frame or lead frame, and wherein the second temperature sense terminal is a second press-fit pin attached to the clip frame or lead frame.

8. The power semiconductor module of claim 1, wherein the integrated current source is a temperature dependent current source.

9. The power semiconductor module of claim 1, wherein the integrated current source is a constant current source.

10. A discrete power semiconductor device, comprising:
a power transistor die attached to a substrate;
an active temperature sensor die that includes an integrated current source;
a mold compound encapsulating the power transistor die and the active temperature sensor die;
a first temperature sense lead electrically connected to a first contact pad of the active temperature sensor die and at least partly uncovered by the mold compound; and
a second temperature sense lead electrically connected to a second contact pad of the active temperature sensor die and at least partly uncovered by the mold compound.

11. The discrete power semiconductor device of claim 10, wherein the active temperature sensor die is attached to the substrate.

12. The discrete power semiconductor device of claim 11, wherein the power transistor die and the active temperature sensor die are soldered to the substrate.

13. The discrete power semiconductor device of claim 11, wherein the power transistor die and the active temperature sensor die are sintered to the substrate.

14. The discrete power semiconductor device of claim 10, further comprising:
a metal clip attached to a contact pad of the power transistor die that faces away from the substrate,
wherein the active temperature sensor die is attached to the metal clip.

15. The discrete power semiconductor device of claim 10, wherein the active temperature sensor die is attached to a side of the power transistor die that faces away from the substrate.

16. The discrete power semiconductor device of claim 10, wherein the substrate is a die paddle of a lead frame, wherein the first temperature sense lead and the second temperature sense lead are part of the lead frame, wherein the first contact pad of the active temperature sensor die is electrically connected to the first temperature sense lead by a first bond wire embedded in the mold compound, and wherein the second contact pad of the active temperature sensor die is electrically connected to the second temperature sense lead by a second bond wire embedded in the mold compound.

17. The discrete power semiconductor device of claim 16, wherein the active temperature sensor die is attached to the die paddle.

18. A method of producing a power semiconductor module, the method comprising:
housing a plurality of power semiconductor dies and an active temperature sensor die in an electrically insulative frame, the active temperature sensor die including an integrated current source;
electrically interconnecting the plurality of power semiconductor dies to form a power electronics circuit;
electrically connecting a first temperature sense terminal to a first contact pad of the active temperature sensor die; and
electrically connecting a second temperature sense terminal to a second contact pad of the active temperature sensor die.

19. The method of claim 18, further comprising:
before housing the plurality of power semiconductor dies and the active temperature sensor die in the electrically insulative frame, attaching the plurality of power semiconductor dies and the active temperature sensor die to a substrate.

20. The method of claim 19, wherein attaching the plurality of power semiconductor dies and the active temperature sensor die to the substrate comprises concurrently sintering the plurality of power semiconductor dies and the active temperature sensor die to the substrate.

21. The method of claim 18, further comprising:
housing a clip frame or lead frame in the electrically insulative frame above the plurality of power semiconductor dies;
electrically connecting the clip frame or lead frame to the plurality of power semiconductor dies; and
attaching the active temperature sensor die to the clip frame or lead frame.
